(19) United States
(12) Patent Application Publication
(10) Pub. No.: US 2025/0107320 A1
(43) Pub. Date: Mar. 27, 2025

(54) ORGANIC LIGHT-EMITTING TRANSISTOR AND PREPARATION METHOD THEREFOR, AND DISPLAY PANEL

(71) Applicant: BOE Technology Group Co., Ltd., Beijing (CN)

(72) Inventors: Juan ZHANG, Beijing (CN); Mengna SUN, Beijing (CN); Zhiqiang JIAO, Beijing (CN)

(21) Appl. No.: 18/291,235

(22) PCT Filed: Sep. 22, 2022
(86) PCT No.: PCT/CN2022/120501

§ 371 Date: Jan. 23, 2024

(30) Foreign Application Priority Data
Nov. 25, 2021 (CN) 202111412209.5

(51) Int. Cl. H10K 50/805; H10K 50/30; H10K 71/60

(52) U.S. Cl. CPC H10K 50/805; H10K 50/30; H10K 71/60

(57) ABSTRACT

An organic light-emitting transistor and a preparation method therefor, and a light-emitting panel. The organic light-emitting transistor comprises: a substrate; a gate layer, which is arranged on one side of the substrate; a gate insulating layer, which is arranged on the side of the gate layer that is away from the substrate; a first source electrode, which is arranged on the side of the gate insulating layer that is away from the substrate; a light-emitting functional layer, which is arranged on the side of the first source electrode that is away from the substrate; and a first drain electrode, which is arranged on the side of the light-emitting functional layer that is away from the substrate, wherein the surface of the side of the first source electrode that is away from the substrate is provided with a first grating structure.

### CROSS-REFERENCE TO RELATED APPLICATIONS

The present application is a U.S. National Phase Entry of International Application No. PCT/CN2022/120501, having an international filing date of Sep. 22, 2022, which claims priority to Chinese Patent Application No. 202111412209.5 filed to the CNIPA on Nov. 25, 2021 and entitled “Organic Light-Emitting Transistor and Preparation Method Therefor, and Display Panel”. The entire contents of the above-identified applications are incorporated into the present disclosure by reference.

### TECHNICAL FIELD

Embodiments of the present disclosure relate to, but are not limited to, the field of display technology, and more particularly, to an organic light-emitting transistor, a preparation method therefor and a display panel.

### BACKGROUND

Organic Light-Emitting Transistor (OLET) is a device which integrates the switching function of an Organic Field-Effect Transistor (OFET) and the electroluminescence function of an Organic Light-Emitting Diode (OLED). OLET device has become one of the development trends of display technology in the future because of its simple structure, mature preparation process, thin and light devices and easy miniaturization. Therefore it is necessary to study it deeply. The working principle of OLET device is that the gate voltage not only controls the source and drain current of the Thin Film Transistor (TFT) part, but also controls the area and light intensity of light-emitting regions. However, the OLET with transverse structure prepared in previous years is easy to cause the problems of high working voltage, low efficiency, short service life and small aperture ratio of the device due to the low carrier mobility of organic evaporation materials.

The OLET devices with vertical structure can improve the problems of the low carrier mobility of organic materials of the OLET with transverse structure and the small light-emitting region of the device, and at the same time, improve the efficiency of the device and reduce the working voltage of the device. In addition, when the transmittance of a gate, a source and a drain is high, surface luminescence can be realized. The working principle is that the application of Vgs can increase or decrease the number of induced electrons or holes, so as to further improve the balance rate of electrons and holes in the light-emitting region, and then improve the light-emitting performance of the device.

Although the performance of the OLET with vertical structure has been improved with respect to that of the OLET with transverse structure, a large number of photons in the device are confined inside the device and cannot be effectively emitted due to the waveguide effect, substrate effect and Surface Plasmon Polariton (SPP) effect caused by the difference of refractive index between film layers within the device, and therefore, the efficiency of the device is still low.

### SUMMARY

The following is a summary of subject matter described herein in detail. The summary is not intended to limit the protection scope of the present disclosure.

Embodiments of the present disclosure provide an organic light-emitting transistor, which comprises:
a substrate;
a gate layer arranged on a side of the substrate;
a gate insulating layer arranged on a side of the gate layer away from the substrate;
a first source electrode arranged on a side of the gate insulating layer away from the substrate;
a functional emitting layer arranged on a side of the first source electrode away from the substrate; and
a first drain electrode arranged on a side of the functional emitting layer away from the substrate,
wherein a surface on a side of the first source electrode away from the substrate has a first grating structure.

In an exemplary embodiment, the first grating structure comprises a base layer and a plurality of protrusions arranged on the base layer, the plurality of protrusions are arranged in sequence along a first direction and extend along a second direction, and the first direction intersects the second direction.

In an exemplary embodiment, the heights of the plurality of protrusions of the first grating structure are all the same.

In an exemplary embodiment, protrusions arranged in a peripheral region of the base layer of the first grating structure has a first height, protrusions arranged in a middle region of the base layer of the first grating structure has a second height, and the first height is greater than the second height.

In an exemplary embodiment, the heights of the protrusions gradually increase along a direction from the middle region to the peripheral region.

In an exemplary embodiment, a surface on a side of the first grating structure away from the substrate is a curved structure.

In an exemplary embodiment, a surface on a side of the gate insulating layer away from the substrate has a second grating structure, the first source electrode has a uniform thickness, and the first grating structure and the second grating structure have matching shapes and the same period.

In an exemplary embodiment, the surface on a side of the first source electrode close to the substrate is a plane.

In an exemplary embodiment, the heights of the plurality of protrusions are all H; or,
the protrusions arranged in the peripheral region of the base layer of the first grating structure have a first height, the protrusions arranged in the middle region of the base layer of the first grating structure have a second height, and a height of protrusions with the smallest height is H;
H is 65 nm to 112 nm;
a spacing width of the first grating structure is 245 nm to 340 nm, and the period of the first grating structure is 274 nm to 650 nm.

In an exemplary embodiment,
in an organic light-emitting transistor emitting blue light, H is 65 nm to 75 nm, the spacing width of the first grating structure is 245 nm to 255 nm, and the period of the first grating structure is 274 nm to 486 nm; or
in an organic light-emitting transistor emitting green light, H is 78 nm to 92 nm, the spacing width of the first grating structure is 275 nm to 285 nm, and the period of the first grating structure is 303 nm to 591 nm; or
in an organic light-emitting transistor emitting yellow light, H is 84 nm to 100 nm, the spacing width of the first grating structure is 295 nm to 305 nm, and the period of the first grating structure is 415 nm to 620 nm; or
in an organic light-emitting transistor emitting red light, H is 90 nm to 112 nm, the spacing width of the first grating structure is 330 nm to 340 nm, and the period of the first grating structure is in the range of 335 nm to 650 nm.

In an exemplary embodiment, in a plane perpendicular to the substrate, the cross-sectional shape of the protrusions is a triangle, a semicircle or a trapezoid.

In an exemplary embodiment, the surface on a side of the first grating structure away from the substrate is in a grid-like shape or a hole-like shape.

In an exemplary embodiment, a material of the first source electrode is selected from any one of a metal, indium tin oxide, carbon nanotubes, monolayer graphene and silver nanowires, and the metal is any one of gold, silver, copper, aluminum, magnesium and alloys thereof.

In an exemplary embodiment, a material of the gate insulating layer is selected from any one or more of alumina, titanium dioxide, silicon nitrides, silicon oxides, silicon oxynitride, polymethyl methacrylate, polyvinyl alcohol, ethylene oxide and polyacrylic acid.

In an exemplary embodiment,
a material of the gate layer is selected from any one or more of indium tin oxide, gold, silver, aluminum, and magnesium;
a material of the first drain electrode is selected from any one or more of gold, silver, copper, aluminum, and magnesium.

In an exemplary embodiment, the functional emitting layer comprises:
a hole transport layer arranged on a side of the first source electrode away from the substrate;
an emitting layer arranged on a side of the hole transport layer away from the substrate; and
an electron transport layer arranged on a side of the emitting layer away from the substrate.

Embodiments of the present disclosure also provide a light-emitting panel, which comprises a plurality of organic light-emitting transistors as described above.

In an exemplary embodiment, the light-emitting panel further comprises:
a switching transistor arranged between the substrate and the gate layer, the switching transistor comprising a second source electrode and a second drain electrode, and the second drain electrode being electrically connected with the gate layer and the second source electrode, respectively;
a thin film encapsulation layer arranged on a side of the first drain electrode away from the substrate;
a BM photoresist layer and a color film layer arranged on a side of the thin film encapsulation layer away from the substrate; and
a pixel definition layer arranged between a plurality of organic light-emitting transistors.

Embodiments of the present disclosure further provide a preparation method for the organic light-emitting transistor, which comprises:
S10: forming a gate layer on a side of the substrate;
S20: forming a gate insulating layer with a second grating structure on a side of the gate layer away from the substrate;
S30: forming a first source electrode with uniform thickness on a side of the gate insulating layer with the second grating structure away from the substrate, wherein a surface on a side of the first source electrode away from the substrate has a first grating structure;
S40: forming a functional emitting layer on a side of the first source electrode away from the substrate; and
S50: forming a first drain electrode on a side of the functional emitting layer away from the substrate.

In an exemplary embodiment, Step S20 comprises:
S21: forming an organic polymer semiconductor film with the second grating structure from an organic polymer semiconductor material using a spin coating process and an imprinting process, to obtain a gate insulating layer with the second grating structure on a surface on a side away from the substrate;
wherein the organic polymer semiconductor material is selected from any one or more of polymethyl methacrylate, polyvinyl alcohol, polyethylene oxide and polyacrylic acid.

In an exemplary embodiment, Step S20 comprises:
S21′: forming a silicon-containing inorganic semiconductor film from a silicon-containing inorganic semiconductor material using a chemical vapor deposition process, and forming the second grating structure from the silicon-containing inorganic semiconductor film using a dry etching process, to obtain a gate insulating layer with the second grating structure on a surface on a side away from the substrate;
wherein the silicon-containing inorganic semiconductor material is selected from any one or more of silicon nitrides, silicon oxides and silicon oxynitride.

In an exemplary embodiment, Step S21′ comprises: forming a first silicon-containing inorganic semiconductor film from a first silicon-containing inorganic semiconductor material using a chemical vapor deposition process, forming a second initial grating structure from the first silicon-containing inorganic semiconductor film using a dry etching process, and depositing a second silicon-containing inorganic semiconductor material on the first silicon-containing inorganic semiconductor film of the second initial grating structure using a chemical vapor deposition process, to obtain a gate insulating layer with the second grating structure on a surface on a side away from the substrate;
wherein the second initial grating structure and the second grating structure each comprise a plurality of protrusions, and in a plane perpendicular to the substrate, the cross-sectional shape of the protrusions of the second initial grating structure is a triangle, and the cross-sectional shape of the protrusions of the second grating structure is a rounded trapezoid.

In an exemplary embodiment, the first silicon-containing inorganic semiconductor material and the second silicon-containing inorganic semiconductor material are of the same material or different materials.

In an exemplary embodiment, Step S20 comprises:
S21″: forming a metal oxide film from a metal oxide using a chemical vapor deposition process or an atomic layer deposition process, and forming the second grating structure from the metal oxide film using a dry etching process, to obtain a gate insulating layer with the second grating structure on a surface on a side away from the substrate;
wherein the metal oxide is selected from any one or more of alumina and titanium dioxide.

In an exemplary embodiment, Step S21″ comprises: forming a first metal oxide film from a first metal oxide using a chemical vapor deposition process or an atomic layer deposition process, forming a second initial grating structure from the first metal oxide film using a dry etching process, and depositing a second metal oxide on the first metal oxide film of the second initial grating structure using a chemical vapor deposition process or an atomic layer deposition process, to obtain a gate insulating layer with the second grating structure on a surface on a side away from the substrate;
wherein the second initial grating structure and the second grating structure each comprise a plurality of protrusions, and in a plane perpendicular to the substrate, the cross-sectional shape of the protrusions of the second initial grating structure is a triangle, and the cross-sectional shape of the protrusions of the second grating structure is a rounded trapezoid.

In an exemplary embodiment, the first metal oxide and the second metal oxide are of the same material or different materials.

In an exemplary embodiment, Step S30 comprises:
making the plurality of protrusions of the second grating structure of the gate insulating layer have different heights using an etching process, wherein the protrusions arranged in a peripheral region have a third height, the protrusions arranged in a middle region have a fourth height, and the third height being greater than the fourth height; and
forming a first source electrode with uniform thickness on a side of the gate insulating layer away from the substrate, wherein a surface on a side of the first source electrode away from the substrate have a first grating structure.

Embodiments of the present disclosure further provide a preparation method for the organic light-emitting transistor, which comprises:
S100: forming a gate layer on a side of the substrate;
S200: forming a gate insulating layer with a plane on a side of the gate layer away from the substrate;
S300: forming a first source electrode with a first grating structure on a side of the gate insulating layer away from the substrate;
S400: forming a functional emitting layer on a side of the first source electrode away from the substrate; and
S500: forming a first drain electrode on a side of the functional emitting layer away from the substrate.

In an exemplary embodiment, Step S300 comprises:
S301: forming a metal film from a metal using a vacuum evaporation process, and forming a first grating structure from the metal film using a dry etching process, to obtain a first source electrode with a first grating structure; wherein the metal is selected from any one or more of gold, silver, copper, aluminum, and magnesium.

In an exemplary embodiment, Step S301 comprises:
forming the metal film from the metal using a vacuum evaporation process, and forming a first initial grating structure from the metal film using a dry etching process; and
making a plurality of protrusions of the first initial grating structure have different heights using an etching process, wherein the protrusions arranged in a peripheral region have a first height, the protrusions arranged in a middle region have a second height, and the first height is greater than the second height, so as to obtain the first source electrode with the first grating structure on a surface on a side away from the substrate.

In an exemplary embodiment, Step S300 comprises:
S301′: forming a film with a grid-like surface from any one or more of materials of carbon nanotubes, monolayer graphene and silver nanowires using a spin coating process, to obtain the first source electrode with the first grating structure.

In an exemplary embodiment, Step S300 comprises:
S301″: forming a film with a hole-like surface from indium tin oxide using a mask plate in a magnetron sputtering process, to obtain the first source electrode with a first grating structure.

In an exemplary embodiment, the step S301″ includes:
forming a film with a hole-like surface from indium tin oxide using a mask plate in a magnetron sputtering process, to obtain an indium tin oxide film with a first initial grating structure; and
making a plurality of protrusions of the first initial grating structure have different heights using an etching process, wherein the protrusions arranged in a peripheral region have a first height, the protrusions arranged in a middle region have a second height, and the first height is greater than the second height, so as to obtain the first source electrode with the first grating structure on a surface on a side away from the substrate.

Other features and advantages of the present disclosure will be set forth in the following specification, and partially become apparent from the specification or are understood by implementing the present application. Other advantages of the present disclosure may be achieved and obtained through solutions described in the specification and drawings.

### BRIEF DESCRIPTION OF DRAWINGS

The accompany drawings are used to provide further understanding of the technical solution of the present disclosure, and form a part of the description. The accompany drawings and embodiments of the present disclosure are adopted to explain the technical solution of the present disclosure, and do not form limits to the technical solution of the present disclosure.

FIG. 1 is a schematic diagram of a structure of an organic light-emitting transistor according to an exemplary embodiment of the present disclosure;

FIG. 2 is a schematic diagram of a structure of a first grating structure of an organic light-emitting transistor according to an exemplary embodiment of the present disclosure;

FIG. 3 is a schematic diagram of a first grating structure of a curved structure of an organic light-emitting transistor according to an exemplary embodiment of the present disclosure;

FIG. 4 is a schematic diagram of a structure of a grating structure of an organic light-emitting transistor according to another exemplary embodiment of the present disclosure;

FIG. 5 is a schematic diagram of a structure of a full-color light-emitting panel according to an exemplary embodiment of the present disclosure;

FIG. 6 is a cross-sectional SEM view of a gate insulating layer with a second grating structure on a surface on a side away from a substrate, formed from PMMA, according to an exemplary embodiment of the present disclosure;

FIG. 7 is a cross-sectional SEM view of a gate insulating layer with isosceles triangular protrusions, formed from SiOₓ, according to an exemplary embodiment of the present disclosure;

FIG. 8 is a cross-sectional SEM view of a gate insulating layer with rounded trapezoidal protrusions, formed from SiOₓ, according to an exemplary embodiment of the present disclosure;

FIG. 9 is a cross-sectional SEM view of a gate insulating layer with rounded trapezoidal protrusions, formed from Al₂O₃, according to an exemplary embodiment of the present disclosure;

FIG. 10 is a cross-sectional SEM view of a first source electrode with a grid-like first grating structure on a surface on a side away from a substrate, formed from carbon nanotubes, according to an exemplary embodiment of the present disclosure;

FIG. 11 is a cross-sectional SEM view of a first source electrode with a grid-like first grating structure on a surface on a side away from a substrate, formed from silver nanowires, according to an exemplary embodiment of the present disclosure;

FIG. 12 is a cross-sectional SEM view of a first source electrode with a hole-like first grating structure on a surface on a side away from a substrate, formed from ITO, according to an exemplary embodiment of the present disclosure.

Meanings of reference signs in the accompanying drawings are as follows:
10—Substrate; 20—Gate Layer; 30—Gate Insulating Layer; 40—First Source Electrode; 50—Functional emitting layer; 60—First Drain Electrode; 70—Thin Film Transistor; 71—Second Source Electrode; 72—Second Drain Electrode; 80—Thin Film Encapsulation Layer; 90—BM Photoresist Layer; 100—Color Film Layer CF; 110—Pixel Definition Layer.

### DETAILED DESCRIPTION

To make the objectives, technical solutions, and advantages of the present disclosure clearer, the embodiments of the present disclosure will be described in detail below in combination with the accompany drawings. It is to be noted that the embodiments in the present disclosure and features in the embodiments may be randomly combined with each other if there is no conflict.

Implementations herein may be implemented in multiple different forms. Those of ordinary skills in the art can readily appreciate a fact that the implementations and contents may be varied into various forms without departing from the spirit and scope of the present disclosure. Therefore, the present disclosure should not be explained as being limited to the contents recorded in the following implementations only. The embodiments and features in the embodiments of the present disclosure may be randomly combined with each other in case of no conflicts.

In the accompanying drawings, a size of a constituent element, and a thickness of a layer or a region is sometimes exaggerated for clarity. Therefore, any one embodiment of the present disclosure is not necessarily limited to dimensions shown in the drawings, and the shapes and sizes of the components in the accompanying drawings do not reflect actual scales. In addition, the accompanying drawings schematically show an ideal example, and any one embodiment of the present disclosure is not limited to the shapes, values, or the like shown in the accompanying drawings.

In the description of the present specification, it should be noted that the orientation or positional relationship indicated by the terms “one side”, “one end”, “other end”, “left”, “right”, and the like is based on the orientation or positional relationship shown in the drawings, only for convenience of describing the present invention and simplifying the description, and not to indicate or imply that the indicated structure has a specific orientation, is constructed or operates in a specific orientation, and therefore cannot be understood as a limitation of the present invention.

Ordinal numerals “first”, “second”, etc., in the specification are set not to form limits in number but only to avoid the confusion of composition elements.

In the specification, a “film” and a “layer” are interchangeable. For example, a “conductive layer” may be replaced with a “conductive film” sometimes. Similarly, a “quantum dot film” may sometimes be replaced by a “quantum dot layer”.

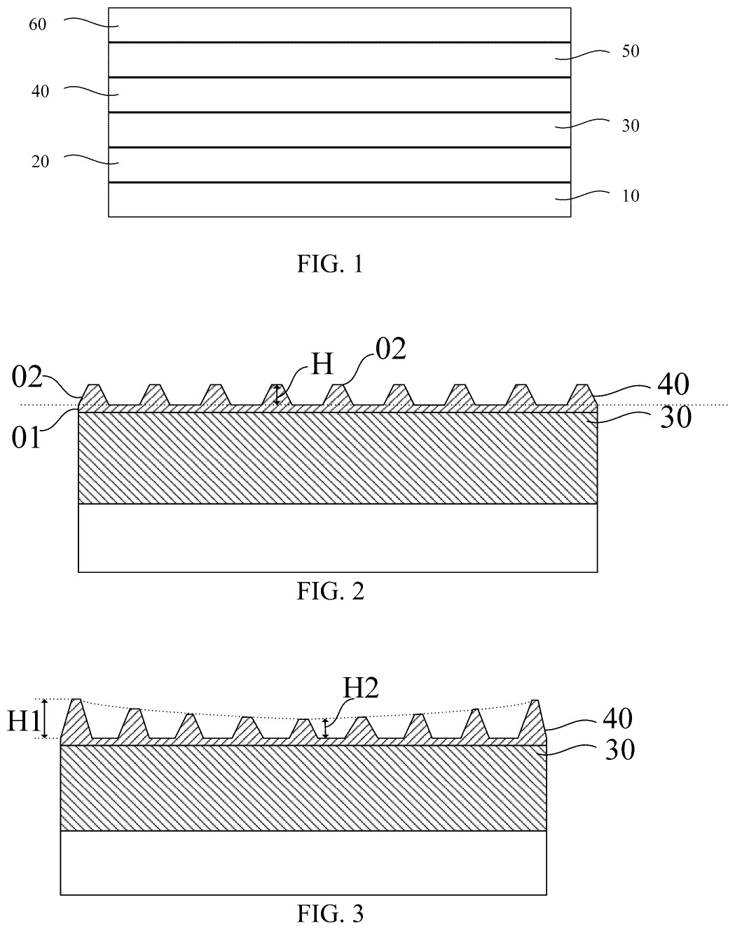

Embodiments of the present disclosure provide an organic light-emitting transistor. FIG. 1 is a schematic diagram of a structure of an organic light-emitting transistor according to an exemplary embodiment of the present disclosure. As shown in FIG. 1, the organic light-emitting transistor comprises:
a substrate 10;
a gate layer 20 arranged on a side of the substrate 10;
a gate insulating layer 30 arranged on a side of the gate layer 20 away from the substrate 10;
a first source electrode 40 arranged on a side of the gate insulating layer 30 away from the substrate 10;
a functional emitting layer 50 arranged on a side of the first source electrode 40 away from the substrate 10; and
a first drain electrode 60 arranged on a side of the functional emitting layer 50 away from the substrate 10;
wherein a surface on a side of the first source electrode 40 away from the substrate 10 has a first grating structure.

In the organic light-emitting transistor according to embodiments of the present disclosure, the surface on a side of the first source electrode away from the substrate is arranged as a grating structure, which can reduce the waveguide effect, the substrate effect and the SPP effect caused by the difference of refractive index between film layers within the device, so that more photons become effective photons, thereby enabling more light to be emitted from the organic light-emitting transistor and improving the efficiency of the organic light-emitting transistor.

In an exemplary embodiment, the first grating structure comprises a base layer 01 and a plurality of protrusions 02 arranged on the base layer 01, the plurality of protrusions 02 are arranged in sequence along a first direction and extend along a second direction, and the first direction intersects the second direction. FIG. 2 is a schematic diagram of a structure of a first grating structure of an organic light-emitting transistor according to an exemplary embodiment of the present disclosure and the left-right direction in FIG. 2 is the first direction.

In an exemplary embodiment, the heights of the plurality of protrusions of the first grating structure are all the same.

In an exemplary embodiment, the protrusions arranged in a peripheral region of the base layer have a first height, the protrusions arranged in a middle region of the base layer have a second height, and the first height is greater than the second height.

In the description of embodiments of the present disclosure, a “peripheral region” is defined as an region near the edge of the base layer of the grating structure in the first direction, and a “middle region” is defined as an region near a center between the edges of opposite sides of the base layer of the grating structure in the first direction. In an exemplary embodiment, the heights of the protrusions gradually increase along a direction from the middle region to the peripheral region.

In an exemplary embodiment, a surface on a side of the first grating structure away from the substrate is a curved structure.

FIG. 3 is a schematic diagram of a first grating structure of a curved structure of an organic light-emitting transistor according to an exemplary embodiment of the present disclosure. As shown in FIG. 3, the grating structure of the organic light-emitting transistor of the exemplary embodiment is a curved structure which is high in both sides and low in the middle. In FIG. 3, H1 denotes a first height and H2 denotes a second height.

The arrangement of the curved structure can improve the line luminescence into surface luminescence or strip luminescence, which not only improves the optical efficiency of organic light-emitting transistors, but also increases the luminescence area.

In an exemplary embodiment, in order to make the surface on a side of the first source electrode away from the substrate have a first grating structure, the surface on a side of the first source electrode close to the substrate may be a plane, at which time the gate insulating layer does not have a grating structure.

In an exemplary embodiment, in order to make the surface on a side of the first source electrode away from the substrate have a first grating structure, a surface on a side of the gate insulating layer away from the substrate has a second grating structure, the first source electrode has a uniform thickness, and the first grating structure and the second grating structure have matching shapes and the same period.

When the surface on a side of the gate insulating layer away from the substrate has a second grating structure, since the first source electrode is formed on the surface of the gate insulating layer and matches the shape of the gate insulating layer, a first source electrode with a first grating structure can be obtained even if the thickness of the first source electrode is uniform.

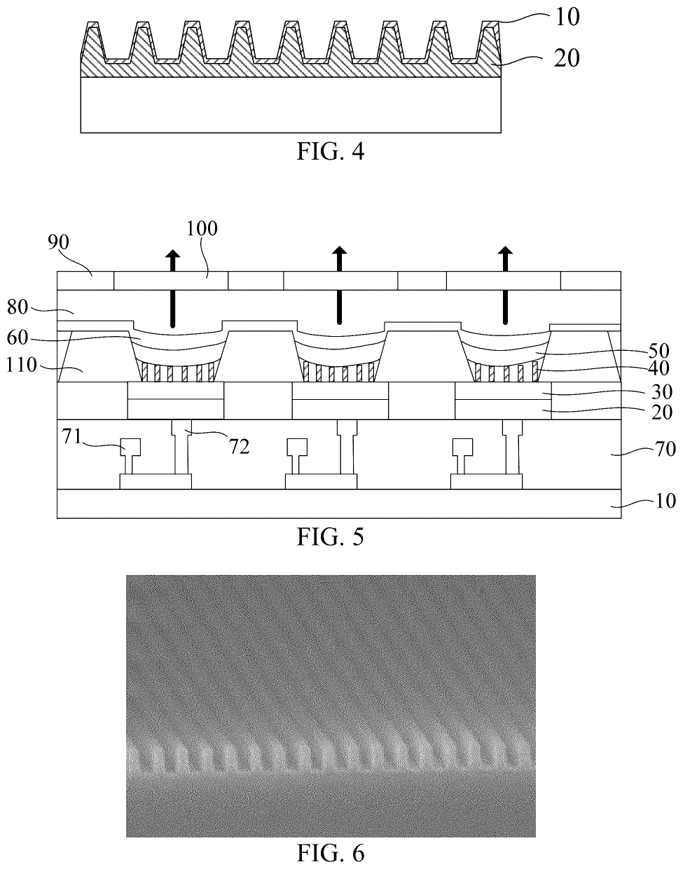

FIG. 4 is a schematic diagram of a structure of a grating structure of an organic light-emitting transistor according to another exemplary embodiment of the present disclosure.

In the organic light-emitting transistor shown in FIG. 2, the surface on a side of the first source electrode 40 close to the gate insulating layer 30 (i.e. the side close to the substrate) is a plane, the surface on a side away from the gate insulating layer 30 (i.e. the side away from the substrate) has a first grating structure, and the gate insulating layer 30 does not have a grating structure. In the organic light-emitting transistor shown in FIG. 4, the surface on a side of the first source electrode 40 away from the gate insulating layer 30 (i.e. the side away from the substrate) has a first grating structure, the surface on a side of the gate insulating layer 30 close to the first source electrode 40 (i.e. the side away from the substrate) has a second grating structure, the first source electrode 40 has a uniform thickness, and the first grating structure and the second grating structure have matching shapes and the same period.

When the heights of a plurality of protrusions of the first grating structure are all the same, the height of each protrusion is defined as H. In the organic light-emitting transistor shown in FIG. 2, the heights of the plurality of protrusions of the first grating structure are all H.

When the protrusions arranged in the peripheral region of the base layer of the first grating structure have a first height, and the protrusions arranged in the middle region of the base layer have a second height, the height of protrusions with the smallest height in the first grating structure is defined as H.

In an exemplary embodiment, H is 65 nm to 112 nm.

In an exemplary embodiment, a spacing width of the first grating structure is 245 nm to 340 nm, and the period of the first grating structure is 274 nm to 650 nm.

In an exemplary embodiment, in an organic light-emitting transistor emitting blue light, H is 65 nm to 75 nm, for example, H may be 65 nm, 66 nm, 67 nm, 68 nm, 69 nm, 70 nm, 71 nm, 72 nm, 73 nm, 74 nm, and 75 nm; the spacing width of the first grating structure is 245 nm to 255 nm, for example, it may be 245 nm, 246 nm, 247 nm, 248 nm, 249 nm, 250 nm, 251 nm, 252 nm, 253 nm, 254 nm, and 255 nm; and the period of the first grating structure is 274 nm to 486 nm, for example, it may be 374 nm, 390 nm, 410 nm, 430 nm, 450 nm, 470 nm, and 486 nm.

In an exemplary embodiment, in an organic light-emitting transistor emitting green light, H is 78 nm to 92 nm, for example, H may be 78 nm, 80 nm, 82 nm, 84 nm, 86 nm, 88 nm, 90 nm, and 92 nm; the spacing width of the first grating structure is 275 nm to 285 nm, for example, it may be 275 nm, 276 nm, 277 nm, 278 nm, 279 nm, 280 nm, 281 nm, 282 nm, 283 nm, 284 nm, and 285 nm; and the period of the first grating structure is 303 nm to 591 nm, for example, it may be 303 nm, 350 nm, 400 nm, 440 nm, 500 nm, 550 nm, and 591 nm.

In an exemplary embodiment, in an organic light-emitting transistor emitting yellow light, H is 84 nm to 100 nm, for example, H may be 84 nm, 86 nm, 88 nm, 90 nm, 92 nm, 94 nm, 96 nm, 98 nm, and 100 nm; the spacing width of the first grating structure is 295 nm to 305 nm, for example, it may be 295 nm, 296 nm, 297 nm, 298 nm, 299 nm, 300 nm, 301 nm, 302 nm, 303 nm, 304 nm, and 305 nm; and the period of the first grating structure is 415 nm to 620 nm, for example, it may be 415 nm, 470 nm, 500 nm, 550 nm, 600 nm, and 620 nm.

In an exemplary embodiment, in an organic light-emitting transistor emitting red light, H is 90 nm to 112 nm, for example, H may be 90 nm, 92 nm, 94 nm, 96 nm, 98 nm, 100 nm, 102 nm, 104 nm, 106 nm, 108 nm, 110 nm, and 112 nm; the spacing width of the first grating structure is 330 nm to 340 nm, for example, it may be 330 nm, 331 nm, 332 nm, 333 nm, 334 nm, 335 nm, 336 nm, 337 nm, 338 nm, 339 nm, and 340 nm; and the period of the first grating structure is 335 nm to 650 nm, for example, it may be 335 nm, 350 nm, 400 nm, 450 nm, 500 nm, 550 nm, 600 nm, and 650 nm.

In an exemplary embodiment, in a plane perpendicular to the substrate, the cross-sectional shape of the protrusions of the first grating structure is a triangle (e.g. a rounded triangle), a semicircle, or a trapezoid (e.g. an isosceles trapezoid, a rounded trapezoid).

In an exemplary embodiment, the surface on a side of the first grating structure away from the substrate is in a grid-like shape or a hole-like shape.

In an exemplary embodiment, a material of the first source electrode may be selected from any one or more of a metal, indium tin oxide, carbon nanotubes, monolayer graphene and silver nanowires, and the metal may be selected from any one or more of gold, silver, copper, aluminum, and magnesium. When gold in the metals is selected as the material of the first source electrode, the first source electrode can obtain better work function, conductivity and light transmittance. The thickness of the first source electrode may be in the range of 65 Å to 140 Å.

In an exemplary embodiment, the material of the gate insulating layer may be selected from any one or more of alumina (Al₂O₃), titanium dioxide (TiO₂), Ta₂O₃, silicon nitrides (SiNₓ), silicon oxides (SiOₓ, such as SiO₂), silicon oxynitride (SiON), polymethyl methacrylate (PMMA), polyvinyl alcohol (PVA), polyethylene oxide (PEO), and polyacrylic acid (PAA). The thickness of the gate insulating layer may be 40 nm to 100 nm.

In an exemplary embodiment, the material of the gate layer may be selected from any one or more of indium tin oxide, gold, silver, aluminum, and magnesium. The thickness of the gate layer may be in the range of 40 nm to 150 nm.

In an exemplary embodiment, the material of the first drain electrode may be selected from any one or more of gold, silver, copper, aluminum, and magnesium. When gold is used as the material of the first drain electrode, the first drain electrode can obtain better work function, conductivity and light transmittance. The thickness of the first drain electrode may be in the range of 65 Å to 140 Å.

In an exemplary embodiment, the functional emitting layer comprises:
a Hole Transport Layer (HTL) arranged on a side of the first source electrode away from the substrate;
an Emitting Layer (EML) arranged on a side of the hole transport layer away from the substrate; and
an Electron Transport Layer (ETL) arranged on a side of the emitting layer away from the substrate.

In an exemplary embodiment, the functional emitting layer may further comprise an Electron Block Layer (EBL) arranged between the hole transport layer and the emitting layer, and a Hole Block Layer (HBL) arranged between the emitting layer and the electron transport layer.

The material of the functional emitting layer may be selected from organic transport materials with high mobility and emitting layer materials with high light-emitting efficiency. The material selection and the thickness adjustment of each film layer will have a great influence on the device performance and light-emitting color. Therefore, device structures with different colors are prepared, and the film thickness of each layer of organic materials in the device is quite different. For example, in an organic light-emitting transistor emitting red light, the thickness of the functional emitting layer may be 95 nm to 95+n×165 nm; in an organic light-emitting transistor emitting green light, the thickness of the functional emitting layer may be 205 nm to 205+n×135 nm; in an organic light-emitting transistor emitting blue light, the thickness of the functional emitting layer may be 125 nm to 125+n×115 nm; wherein n may be any integer, for example n=1, 2, 3, . . .

In an exemplary embodiment, the material of the hole injection layer may be selected from any one or more of MoO₃, F4-TCNQ, and HAT-CN.

In an exemplary embodiment, the material of the hole transport layer may be selected from any one or more of NPB, m-MTDATA, NPD, and TPD.

In an exemplary embodiment, the material of the electron block layer may be selected from any one or more of CCP, mCP, and Tris-PCz.

In an exemplary embodiment, the material of the electron transport layer may be selected from any one or more of BCP, Bphen, and TPBI.

The chemical structural formulas of some materials are as follows:

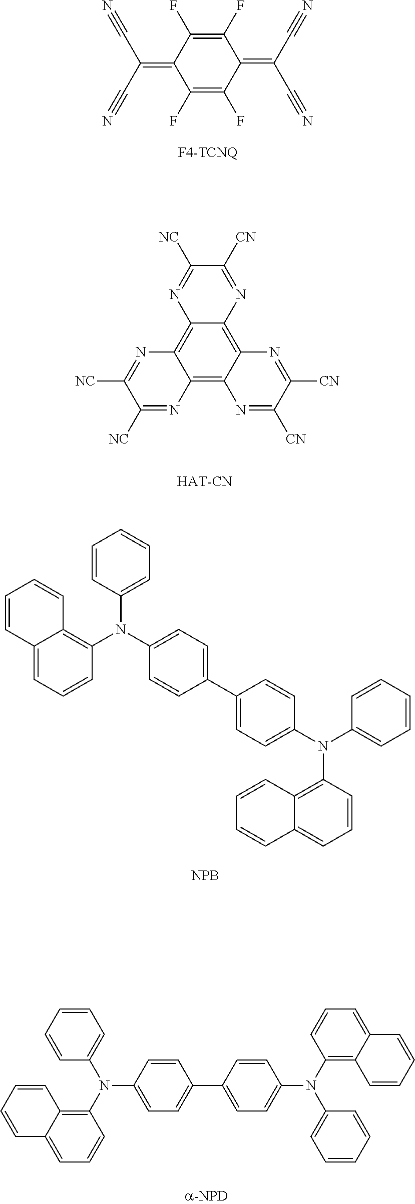 [SMILES: N#CC(C#N)=c1c(F)c(F)c(=C(C#N)C#N)c(F)c1F ; N#Cc1nc2c3nc(C#N)c(C#N)nc3c3nc(C#N)c(C#N)nc3c2nc1C#N ; c1ccc(N(c2ccc(-c3ccc(N(c4ccccc4)c4cccc5ccccc45)cc3)cc2)c2cccc3ccccc23)cc1 ; "NPB" ; c1ccc(N(c2ccc(-c3ccc(N(c4ccccc4)c4cccc5ccccc45)cc3)cc2)c2cccc3ccccc23)cc1]

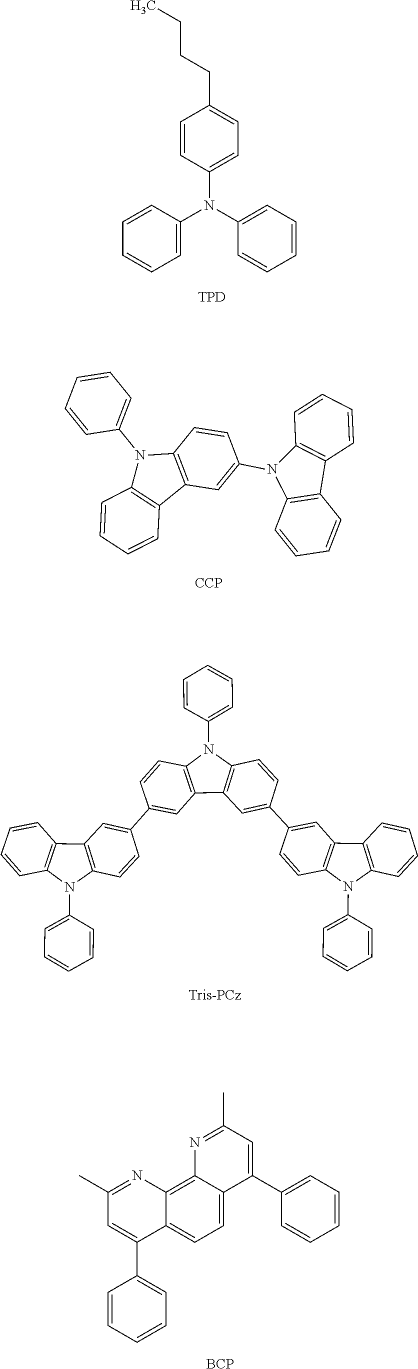

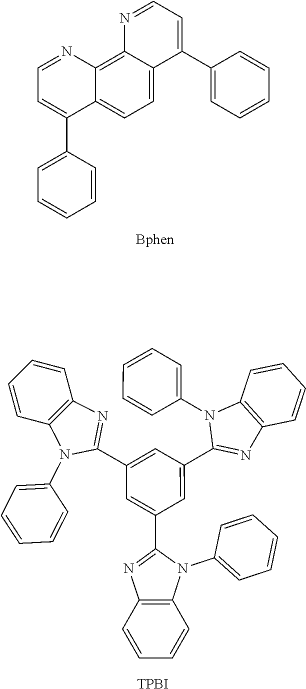

Embodiments of the present disclosure also provide a light-emitting panel, which comprises a plurality of organic light-emitting transistors as described above.

In an exemplary embodiment, the light-emitting panel may further comprise:
a switching transistor arranged between the substrate and the gate layer, the switching transistor comprising a second source electrode and a second drain electrode, and the second drain electrode being electrically connected with the gate layer and the second source electrode, respectively;
a thin film encapsulation layer arranged on a side of the first drain electrode away from the substrate;
a BM photoresist layer and a color film layer arranged on a side of the thin film encapsulation layer away from the substrate; and
a pixel definition layer arranged between a plurality of organic light-emitting transistors.

The light-emitting panel may be the light-emitting panel of any product or part such as a mobile phone, a tablet computer, a television, a display, a laptop computer, a digital photo frame, a navigator, a vehicle-mounted display, a smart watch, and a smart bracelet.

FIG. 5 is a schematic diagram of a structure of a full-color light-emitting panel according to an exemplary embodiment of the present disclosure. In the exemplary embodiment, the full-color light-emitting panel comprises blue light OLET devices, red light OLET devices, and green light OLET devices in sequence from left to right. Each OLET device comprises a substrate 10, a thin film transistor 70 arranged on a side of the substrate 10, a gate layer 20 arranged on a side of the thin film transistor 70 away from the substrate 10, a gate insulating layer 30 arranged on a side of the gate layer 20 away from the substrate 10, a first source electrode 40 arranged on a side of the gate insulating layer 30 away from the substrate 10, a functional emitting layer 50 arranged on a side of the first source electrode 40 away from the substrate 10, and a first drain electrode 60 arranged on a side of the functional emitting layer 50 away from the substrate 10. The functional emitting layer 50 comprises a hole transport layer arranged on a side of the first source electrode 40 away from the substrate 10, an emitting layer arranged on a side of the hole transport layer away from the substrate 10, and an electron transport layer arranged on a side of the emitting layer away from the substrate 10. The thin film transistor 70 comprises a second source electrode 71 and a second drain electrode 72. The first source electrode 40 is electrically connected to the gate layer 20 and the first drain electrode 60, respectively, the second source electrode 71 is electrically connected to one end of the second drain electrode 72, and the other end of the second drain electrode 72 is electrically connected to the gate layer 20.

The organic light-emitting transistor further comprises a Thin Film Encapsulation (TFE) layer 80 arranged on a side of the first drain electrode 60 away from the substrate 10, and a BM photoresist layer 90 and a color film layer CF 100 arranged on a side of the thin film encapsulation layer 80 away from the substrate 10.

A pixel definition layer 110 is arranged between a plurality of organic light-emitting transistors.

The thin film encapsulation layer may be a composite film layer formed of high refractive index material/low refractive index material/high refractive index material. The arrangement of thin film encapsulation layer can improve the light extraction of the device, and function to protect the device from water and oxygen and prolong the service life of the device.

Embodiments of the present disclosure further provide a preparation method for the organic light-emitting transistor, which comprises:
S10: forming a gate layer on a side of the substrate;
S20: forming a gate insulating layer with a second grating structure on a side of the gate layer away from the substrate;
S30: forming a first source electrode with uniform thickness on a side of the gate insulating layer with the second grating structure away from the substrate, wherein a surface on a side of the first source electrode away from the substrate has a first grating structure;
S40: forming an active layer on a side of the first source electrode away from the substrate; and
S50: forming a first drain electrode on a side of the active layer away from the substrate.

In an exemplary embodiment, Step S20 comprises:
S21: forming an organic polymer semiconductor film with the second grating structure from an organic polymer semiconductor material using a spin coating process and an imprinting process, to obtain a gate insulating layer with the second grating structure on a surface on a side away from the substrate;
wherein the organic polymer semiconductor material is selected from any one or more of polymethyl methacrylate, polyvinyl alcohol, polyethylene oxide and polyacrylic acid.

In an exemplary embodiment, Step S20 comprises:
S21: polymethyl methacrylate is formed into a polymethyl methacrylate film with a second grating structure using a spin coating process and an imprinting process, to obtain a gate insulating layer with the second grating structure on a surface on a side away from the substrate;
wherein, the process conditions of the spin coating process include: rotating speed of 800 r/min;

The process conditions of the imprinting process include: imprinting speed of 20 mm/s, demoulding angle of 90°, roller weight of 5.6 kg, and exposure amount of 4900 mj/cm².

In an exemplary embodiment, Step S20 comprises:
S21′: forming a silicon-containing inorganic semiconductor film from a silicon-containing inorganic semiconductor material using a chemical vapor deposition (CVD) process, and forming the second grating structure from the silicon-containing inorganic semiconductor film using a dry etching process, to obtain a gate insulating layer with the second grating structure on a surface on a side away from the substrate;
wherein the silicon-containing inorganic semiconductor material is selected from any one or more of silicon nitrides, silicon oxides and silicon oxynitride.

In an exemplary embodiment, Step S21′ comprises: forming a first silicon-containing inorganic semiconductor film from a first silicon-containing inorganic semiconductor material using a chemical vapor deposition process, forming a second initial grating structure from the first silicon-containing inorganic semiconductor film using a dry etching process, and depositing a second silicon-containing inorganic semiconductor material on the first silicon-containing inorganic semiconductor film of the second initial grating structure using a chemical vapor deposition process, to obtain a gate insulating layer with the second grating structure on a surface on a side away from the substrate;
wherein the second initial grating structure and the second grating structure each comprise a plurality of protrusions, and in a plane perpendicular to the substrate, the cross-sectional shape of the protrusions of the second initial grating structure is a triangle, and the cross-sectional shape of the protrusions of the second grating structure is a rounded trapezoid.

In an exemplary embodiment, the first silicon-containing inorganic semiconductor material and the second silicon-containing inorganic semiconductor material are of the same material or different materials.

In an exemplary embodiment, Step S20 comprises:
S21″: forming a metal oxide film from a metal oxide using a chemical vapor deposition process or an Atomic Layer Deposition (ALD) process, and forming the second grating structure from the metal oxide film using a dry etching process, to obtain a gate insulating layer with the second grating structure on a surface on a side away from the substrate;
wherein the metal oxide is selected from any one or more of alumina and titanium dioxide.

In an exemplary embodiment, Step S21″ comprises: forming a first metal oxide film from a first metal oxide using a chemical vapor deposition process or an atomic layer deposition process, forming a second initial grating structure from the first metal oxide film using a dry etching process, and depositing a second metal oxide on the first metal oxide film of the second initial grating structure using a chemical vapor deposition process or an atomic layer deposition process, to obtain a gate insulating layer with the second grating structure on a surface on a side away from the substrate;
wherein the second initial grating structure and the second grating structure each comprise a plurality of protrusions, and in a plane perpendicular to the substrate, the cross-sectional shape of the protrusions of the second initial grating structure is a triangle, and the cross-sectional shape of the protrusions of the second grating structure is a rounded trapezoid.

In an exemplary embodiment, the first metal oxide and the second metal oxide are of the same material or different materials.

In an exemplary embodiment, Step S30 comprises:
making the plurality of protrusions of the second grating structure of the gate insulating layer have different heights using an etching process, wherein the protrusions arranged in a peripheral region have a third height, the protrusions arranged in a middle region have a fourth height, and the third height is greater than the fourth height; and
forming a first source electrode with uniform thickness on a side of the gate insulating layer away from the substrate, wherein a surface on a side of the first source electrode away from the substrate has a first grating structure.

In an exemplary embodiment,
before Step S10 or Step S100, the preparation method may further comprises: forming a thin film transistor on the substrate, and forming a gate layer on a side of the thin film transistor away from the substrate.

In an exemplary embodiment, the preparation method may further comprise:
after forming a hole transport layer and before forming an emitting layer, forming an electron block layer on a side of the hole transport layer away from the substrate, and then forming an emitting layer on a side of the electron block layer away from the substrate;
after forming the emitting layer and before forming an electron transport layer, forming a hole block layer on a side of the emitting layer away from the substrate, and then forming an electron transport layer on a side of the hole block layer away from the substrate.

In an exemplary embodiment, the preparation method may further comprise: after forming the first drain electrode, forming a thin film encapsulation layer on a side of the first drain electrode away from the substrate, and forming a BM photoresist layer and a color film layer CF on a side of the thin film encapsulation layer away from the substrate.

In an exemplary embodiment, the gate layer may be formed by deposition using magnetron sputtering and then patterned into an electrode of a desired pattern by an etching method.

In an exemplary embodiment, the first source electrode and the first drain electrode may be prepared in a vacuum evaporation manner.

In an exemplary embodiment, the hole transport layer, the electron block layer, the emitting layer, the hole block layer, and the electron transport layer can all be prepared in a vacuum evaporation manner.

In exemplary embodiments, the thin film encapsulation layer may be prepared using CVD, inkjet printing (IJP), or the like.

Embodiments of the present disclosure further provide a preparation method for the organic light-emitting transistor, which comprises:
S100: forming a gate layer on a side of the substrate;
S200: forming a gate insulating layer with a plane on a side of the gate layer away from the substrate;
S300: forming a first source electrode with a first grating structure on a side of the gate insulating layer away from the substrate;
S400: forming a active layer on a side of the first source electrode away from the substrate; and
S500: forming a first drain electrode on a side of the active layer away from the substrate.

In an exemplary embodiment, Step S300 comprises:
S301: forming a metal film from a metal using a vacuum evaporation process, and forming a first grating structure from the metal film using a dry etching process, to obtain a first source electrode with a first grating structure; wherein the metal is selected from any one or more of gold, silver, copper, aluminum, and magnesium.

In an exemplary embodiment, Step S301 comprises:
forming the metal film from the metal using a vacuum evaporation process, and forming a first initial grating structure from the metal film using a dry etching process; and
making a plurality of protrusions of the first initial grating structure have different heights using an etching process, wherein the protrusions arranged in a peripheral region have a first height, the protrusions arranged in a middle region have a second height, and the first height is greater than the second height, so as to obtain the first source electrode with the first grating structure on a surface on a side away from the substrate.

In an exemplary embodiment, Step S300 comprises:
S301′: forming a film with a grid-like surface from any one or more of materials of carbon nanotubes, monolayer graphene and silver nanowires using a spin coating process, to obtain the first source electrode with the first grating structure.

In an exemplary embodiment, Step S300 comprises:
S301″: forming a film with a hole-like surface from indium tin oxide using a mask plate in a magnetron sputtering process, to obtain the first source electrode with a first grating structure.

In an exemplary embodiment, the step S301″ includes:
forming a film with a hole-like surface from indium tin oxide using a mask plate in a magnetron sputtering process, to obtain an indium tin oxide film with a first initial grating structure; and
making a plurality of protrusions of the first initial grating structure have different heights using an etching process, wherein the protrusions arranged in a peripheral region have a first height, the protrusions arranged in a middle region have a second height, and the first height is greater than the second height, so as to obtain the first source electrode with the first grating structure on a surface on a side away from the substrate.

In an exemplary embodiment,
before Step S10 or Step S100, the preparation method may further comprise: forming a thin film transistor on the substrate, and forming a gate layer on a side of the thin film transistor away from the substrate.

In an exemplary embodiment, the preparation method further comprises:
after forming a hole transport layer and before forming an emitting layer, forming an electron block layer on a side of the hole transport layer away from the substrate, and then forming an emitting layer on a side of the electron block layer away from the substrate;
after forming the emitting layer and before forming an electron transport layer, forming a hole block layer on a side of the emitting layer away from the substrate, and then forming an electron transport layer on a side of the hole block layer away from the substrate.

In an exemplary embodiment, the preparation method may further comprise: after forming the first drain electrode, forming a thin film encapsulation layer on a side of the first drain electrode away from the substrate, and forming a BM photoresist layer and a color film layer CF on a side of the thin film encapsulation layer away from the substrate.

In an exemplary embodiment, the gate layer may be formed by deposition using magnetron sputtering and then patterned into an electrode of a desired pattern by an etching method.

In an exemplary embodiment, the first source electrode and the first drain electrode may be prepared in a vacuum evaporation manner.

In an exemplary embodiment, the hole transport layer, the electron block layer, the emitting layer, the hole block layer, and the electron transport layer can all be prepared in a vacuum evaporation manner.

In exemplary embodiments, the thin film encapsulation layer may be prepared using CVD, inkjet printing (IJP), or the like.

Exemplary embodiments of the present disclosure provide a preparation method for a light-emitting panel in which a surface on a side of a first source electrode away from a substrate has a first grating structure, and a surface on a side of a gate insulating layer away from the substrate has a second grating structure, the preparation method comprising:
(1) forming a thin film transistor on a substrate;
(2) forming a gate layer on the thin film transistor using a magnetron sputtering method;
(3) forming a gate insulating layer with a grating structure on the gate layer:
polymethyl methacrylate (PMMA) is formed into a polymethyl methacrylate film with a second grating structure using a spin coating process and an imprinting process, to obtain a gate insulating layer with the second grating structure on a surface on a side away from the substrate; wherein, the process conditions of the coating process include: rotating speed of 800 r/min; the process conditions of the imprinting process include: imprinting speed of 20 mm/s, demoulding angle of 90°, roller weight of 5.6 kg, and exposure amount of 4900 mj/cm²; thickness of the formed gate insulating layer of 80 nm; for every 1 minute increase in coating time, the film thickness increases by 30 nm, and the imprinting speed and the exposure amount should be adjusted according to different film thickness;
(4) forming a first source electrode matching the shape of the gate insulating layer on the gate insulating layer using a magnetron sputtering method or a vacuum evaporation method, to obtain a first source electrode with a first grating structure on a surface on a side away from the substrate (the height of the protrusions of the first grating structure is 65 nm, the spacing width of the first grating structure is 252 nm, and the period of the first grating structure is 370 nm);
(5) forming a hole transport layer on the first source electrode using a vacuum evaporation method;
(6) forming an emitting layer on the hole transport layer using a vacuum evaporation method;
(7) forming an electron transport layer on the emitting layer using a vacuum evaporation method;
(8) forming a first drain electrode on the electron transport layer using a vacuum evaporation method;
(9) forming a thin film encapsulation layer on the first drain electrode using CVD and inkjet printing (IJP); and
(10) forming a BM photoresist layer and a color film layer CF on the thin film encapsulation layer.

FIG. 6 is a cross-sectional SEM view of a gate insulating layer with a second grating structure on a surface on a side away from a substrate, formed from PMMA, according to an exemplary embodiment of the present disclosure.

Exemplary embodiments of the present disclosure provide a preparation method for a light-emitting panel in which a surface on a side of a first source electrode away from a substrate has a first grating structure, and a surface on a side of a gate insulating layer away from the substrate has a second grating structure, the preparation method comprising:
(1) forming a thin film transistor on a substrate;
(2) forming a gate layer on the thin film transistor using a magnetron sputtering method;
(3) forming a gate insulating layer with a grating structure on the gate layer:

SiO₂ is formed into a film by chemical vapor deposition process, and a SiO₂ film is dry etched into a second initial grating structure with isosceles triangular protrusions. Then a SiO₂ film (thickness of 40 nm) is deposited on the surface of the SiO₂ film of isosceles triangle by chemical vapor deposition process, so that the isosceles triangular protrusions are transformed into rounded trapezoidal protrusions, to obtain a gate insulating layer with the second grating structure on a surface on a side away from the substrate; wherein, the process conditions of the chemical vapor deposition process include: power of 1000 W, pressure of 1200 Mpa, plate spacing of 700 mil, and deposition time of 10 min;
(4) forming a first source electrode matching the shape of the gate insulating layer on the gate insulating layer using a magnetron sputtering method or a vacuum evaporation method, to obtain a first source electrode with a first grating structure on a surface on a side away from the substrate (the height of the protrusions of the first grating structure is 70 nm, the spacing width of the first grating structure is 255 nm, and the period of the first grating structure is 430 nm);
(5) forming a hole transport layer on the first source electrode using a vacuum evaporation method;
(6) forming an emitting layer on the hole transport layer using a vacuum evaporation method;
(7) forming an electron transport layer on the emitting layer using a vacuum evaporation method;
(8) forming a first drain electrode on the electron transport layer using a vacuum evaporation method;
(9) forming a thin film encapsulation layer on the first drain electrode using CVD and inkjet printing (IJP); and
(10) forming a BM photoresist layer and a color film layer CF on the thin film encapsulation layer.

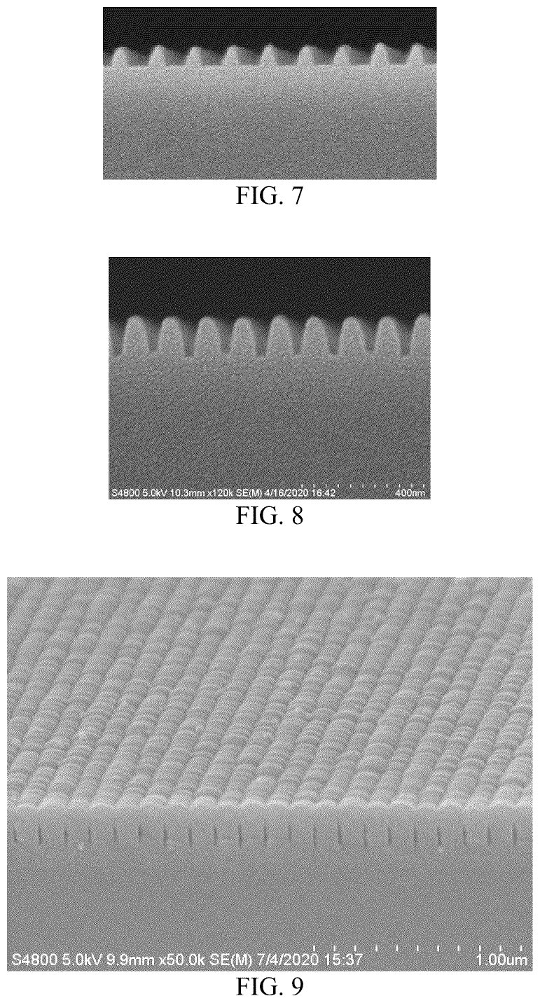

FIG. 7 is a cross-sectional SEM view of a gate insulating layer with isosceles triangular protrusions, formed from SiOₓ, according to an exemplary embodiment of the present disclosure, and FIG. 8 is a cross-sectional SEM view of a gate insulating layer with rounded trapezoidal protrusions, formed from SiOₓ, according to an exemplary embodiment of the present disclosure.

When the thickness of the gate insulating layer with a second grating structure on a surface on a side away from the substrate is larger than the thickness of the first source electrode and the protrusions of the second grating structure are triangular, the sharp corner(s) of the grating structure cannot be eliminated after the first source electrode is formed on the gate insulating layer, resulting in discontinuity of the film layer of the first source electrode, or short circuit between the first source electrode at the sharp corner(s) and the first drain electrode deposited later, which results in the device being unable to be lit normally. At this time, the triangular protrusions can be transformed into a rounded trapezoidal grating to solve the problem of the discontinuity of the film layer of the first source electrode or of the short circuit between the first source electrode at the sharp corner(s) and the first drain electrode deposited later.

Exemplary embodiments of the present disclosure provide a preparation method for a light-emitting panel in which a surface on a side of a first source electrode away from a substrate has a first grating structure, and a surface on a side of a gate insulating layer away from the substrate has a second grating structure, the preparation method comprising:
(1) forming a thin film transistor on a substrate;
(2) forming a gate layer on the thin film transistor using a magnetron sputtering method;
(3) forming a gate insulating layer with a grating structure on the gate layer:
Al₂O₃ is formed into a film by chemical vapor deposition process or atomic layer deposition process, and an Al₂O₃ film is dry etched into a second initial grating structure with isosceles triangular protrusions. Then an Al₂O₃ film is deposited on the surface of the Al₂O₃ film of isosceles triangle by chemical vapor deposition process, so that the isosceles triangular protrusions are transformed into rounded trapezoidal protrusions, to obtain a gate insulating layer with the second grating structure on a surface on a side away from the substrate; wherein, the process conditions of the chemical vapor deposition process include: power of 1000 W, pressure of 1000 Mpa, plate spacing of 680 mil, and deposition time of 15 min;
(4) forming a first source electrode matching the shape of the gate insulating layer on the gate insulating layer using a magnetron sputtering method or a vacuum evaporation method, to obtain a first source electrode with a first grating structure on a surface on a side away from the substrate (the height of the protrusions of the first grating structure is 88 nm, the spacing width of the first grating structure is 268 nm, and the period of the first grating structure is 396 nm);
(5) forming a hole transport layer on the first source electrode using a vacuum evaporation method;
(6) forming an emitting layer on the hole transport layer using a vacuum evaporation method;
(7) forming an electron transport layer on the emitting layer using a vacuum evaporation method;
(8) forming a first drain electrode on the electron transport layer using a vacuum evaporation method;
(9) forming a thin film encapsulation layer on the first drain electrode using CVD and inkjet printing (IJP); and
(10) forming a BM photoresist layer and a color film layer CF on the thin film encapsulation layer.

FIG. 9 is a cross-sectional SEM view of a gate insulating layer with rounded trapezoidal protrusions, formed from Al₂O₃, according to an exemplary embodiment of the present disclosure.

Exemplary embodiments of the present disclosure provide a preparation method for a light-emitting panel in which a surface on a side of a first source electrode away from a substrate has a first grating structure, and a surface on a side of a first source electrode close to the substrate is a plane, and a gate insulating layer is a plane, the preparation method comprising:
(1) forming a thin film transistor on a substrate;
(2) forming a gate layer on the thin film transistor using a magnetron sputtering method;
(3) forming a planar gate insulating layer on the gate layer;
(4) forming, on the gate insulating layer, a first source electrode with a first grating structure on a surface on a side away from the substrate:
a grid-like film is formed on the gate insulating layer from carbon nanotubes using a spin coating process, to obtain a first source electrode with a first grating structure on a surface on a side away from the substrate (the height of the protrusions of the first grating structure is 93 nm, the spacing width of the first grating structure is 315 nm, and the period of the first grating structure is 341 nm); wherein the process conditions of the spin coating process include: rotating speed of 800 rmp, baking temperature of 50° C., and baking time of 20 min;
(5) forming a hole transport layer on the first source electrode using a vacuum evaporation method;
(6) forming an emitting layer on the hole transport layer using a vacuum evaporation method;
(7) forming an electron transport layer on the emitting layer using a vacuum evaporation method;
(8) forming a first drain electrode on the electron transport layer using a vacuum evaporation method;
(9) forming a thin film encapsulation layer on the first drain electrode using CVD and inkjet printing (IJP); and
(10) forming a BM photoresist layer and a color film layer CF on the thin film encapsulation layer.

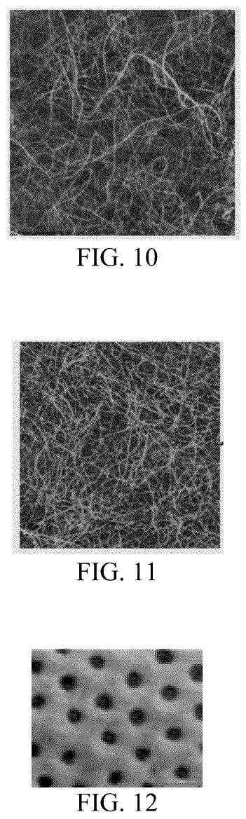

FIG. 10 is a cross-sectional SEM view of a first source electrode with a grid-like first grating structure on a surface on a side away from a substrate, formed from carbon nanotubes, according to an exemplary embodiment of the present disclosure.

Exemplary embodiments of the present disclosure provide a preparation method for a light-emitting panel in which a surface on a side of a first source electrode away from a substrate has a first grating structure, and a surface on a side of a first source electrode close to the substrate is a plane, and a gate insulating layer is a plane, the preparation method comprising:
(1) forming a thin film transistor on a substrate;
(2) forming a gate layer on the thin film transistor using a magnetron sputtering method;
(3) forming a planar gate insulating layer on the gate layer;
(4) forming, on the gate insulating layer, a first source electrode with a first grating structure on a surface on a side away from the substrate:
a grid-like film is formed on the gate insulating layer from silver nanowires using a spin coating process, to obtain a first source electrode with a first grating structure on a surface on a side away from the substrate (the height of the protrusions of the first grating structure is 96 nm, the spacing width of the first grating structure is 302 nm, and the period of the first grating structure is 512 nm); wherein the process conditions of the spin coating process include: rotating speed of 800 rmp, baking temperature of 50° C., and baking time of 20 min;
(5) forming a hole transport layer on the first source electrode using a vacuum evaporation method;
(6) forming an emitting layer on the hole transport layer using a vacuum evaporation method;
(7) forming an electron transport layer on the emitting layer using a vacuum evaporation method;
(8) forming a first drain electrode on the electron transport layer using a vacuum evaporation method;
(9) forming a thin film encapsulation layer on the first drain electrode using CVD and inkjet printing (IJP); and
(10) forming a BM photoresist layer and a color film layer CF on the thin film encapsulation layer.

FIG. 11 is a cross-sectional SEM view of a first source electrode with a grid-like first grating structure on a surface on a side away from a substrate, formed from silver nanowires, according to an exemplary embodiment of the present disclosure.

Exemplary embodiments of the present disclosure provide a preparation method for a light-emitting panel in which a surface on a side of a first source electrode away from a substrate has a first grating structure, and a surface on a side of a first source electrode close to the substrate is a plane, and a gate insulating layer is a plane, the preparation method comprising:
(1) forming a thin film transistor on a substrate;
(2) forming a gate layer on the thin film transistor using a magnetron sputtering method;
(3) forming a planar gate insulating layer on the gate layer;
(4) forming, on the gate insulating layer, a first source electrode with a first grating structure on a surface on a side away from the substrate:
a hole-like film is formed on the gate insulating layer from ITO using a mask plate in a magnetron sputtering process, to obtain a first source electrode with a first grating structure on a surface on a side away from the substrate (the height of the protrusions of the first grating structure is 72 nm, the spacing width of the first grating structure is 252 nm, and the period of the first grating structure is 458 nm); wherein the process conditions of the magnetron sputtering process include: power of 860 W, and pressure of 1350 Mpa;
(5) forming a hole transport layer on the first source electrode using a vacuum evaporation method;
(6) forming an emitting layer on the hole transport layer using a vacuum evaporation method;
(7) forming an electron transport layer on the emitting layer using a vacuum evaporation method;
(8) forming a first drain electrode on the electron transport layer using a vacuum evaporation method;
(9) forming a thin film encapsulation layer on the first drain electrode using CVD and inkjet printing (IJP); and
(10) forming a BM photoresist layer and a color film layer CF on the thin film encapsulation layer.

FIG. 12 is a cross-sectional SEM view of a first source electrode with a hole-like first grating structure on a surface on a side away from a substrate, formed from ITO, according to an exemplary embodiment of the present disclosure;

Although the implementations of the present disclosure are disclosed above, the contents are only implementations adopted to easily understand the present disclosure and not intended to limit the present disclosure. Any skilled person in the art to which the present disclosure pertains may make any modifications and alterations in forms and details of implementation without departing from the spirit and scope of the present disclosure. However, the patent protection scope of the present disclosure should be subject to the scope defined by the appended claims.

1. An organic light-emitting transistor, comprising:
a substrate;
a gate layer arranged on a side of the substrate;
a gate insulating layer arranged on a side of the gate layer away from the substrate;
a first source electrode arranged on a side of the gate insulating layer away from the substrate;
a functional emitting layer arranged on a side of the first source electrode away from the substrate; and
a first drain electrode arranged on a side of the functional emitting layer away from the substrate,
wherein a surface on a side of the first source electrode away from the substrate has a first grating structure.

2. The organic light-emitting transistor according to claim 1, wherein the first grating structure comprises a base layer and a plurality of protrusions arranged on the base layer, the plurality of protrusions are arranged in sequence along a first direction and extend along a second direction, and the first direction intersects the second direction.

3. The organic light-emitting transistor according to claim 2, wherein heights of the plurality of protrusions are all the same.

4. The organic light-emitting transistor according to claim 2, wherein the protrusions arranged in a peripheral region of the base layer have a first height, the protrusions arranged in a middle region of the base layer have a second height, and the first height is greater than the second height.

5. The organic light-emitting transistor according to claim 4, wherein the heights of the protrusions gradually increase along a direction from the middle region to the peripheral region.

6. The organic light-emitting transistor according to claim 5, wherein a surface on a side of the first grating structure away from the substrate is a curved structure.

7. The organic light-emitting transistor according to claim 1, wherein a surface on a side of the gate insulating layer away from the substrate has a second grating structure, the first source electrode has a uniform thickness, and the first grating structure and the second grating structure have matching shapes and the same period.

8. The organic light-emitting transistor according to claim 1, wherein a surface on a side of the first source electrode close to the substrate is a plane.

9. The organic light-emitting transistor according to claim 2, wherein the heights of the plurality of protrusions are all H; or,
the protrusions arranged in the peripheral region of the base layer have a first height, the protrusions arranged in the middle region of the base layer have a second height, and a height of protrusions with the smallest height is H;
H is 65 nm to 112 nm, a spacing width of the first grating structure is 245 nm to 340 nm, and the period of the first grating structure is 274 nm to 650 nm.

10. The organic light-emitting transistor according to claim 9, wherein,
in an organic light-emitting transistor emitting blue light, H is 65 nm to 75 nm, the spacing width of the first grating structure is 245 nm to 255 nm, and the period of the first grating structure is 274 nm to 486 nm; or
in an organic light-emitting transistor emitting green light, H is 78 nm to 92 nm, the spacing width of the first grating structure is 275 nm to 285 nm, and the period of the first grating structure is 303 nm to 591 nm; or
in an organic light-emitting transistor emitting yellow light, H is 84 nm to 100 nm, the spacing width of the first grating structure is 295 nm to 305 nm, and the period of the first grating structure is 415 nm to 620 nm; or
in an organic light-emitting transistor emitting red light, H is 90 nm to 112 nm, the spacing width of the first grating structure is 330 nm to 340 nm, and the period of the first grating structure is 335 nm to 650 nm.

11. The organic light-emitting transistor according to claim 2, wherein, in a plane perpendicular to the substrate, the cross-sectional shape of the protrusions is a triangle, a semicircle or a trapezoid.

12. The organic light-emitting transistor according to claim 2, wherein the surface on a side of the first grating structure away from the substrate is in a grid-like shape or a hole-like shape.

13. The organic light-emitting transistor according to claim 1, wherein a material of the first source electrode is selected from any one of a metal, indium tin oxide, carbon nanotubes, monolayer graphene and silver nanowires, and the metal is any one of gold, silver, copper, aluminum, magnesium and alloys thereof.

14. The organic light-emitting transistor according to claim 1, wherein a material of the gate insulating layer is selected from any one or more of alumina, titanium dioxide, silicon nitrides, silicon oxides, silicon oxynitride, polymethyl methacrylate, polyvinyl alcohol, ethylene oxide and polyacrylic acid.

15. The organic light-emitting transistor according to claim 1, wherein,
a material of the gate layer is selected from any one or more of indium tin oxide, gold, silver, aluminum, and magnesium;
a material of the first drain electrode is selected from any one or more of gold, silver, copper, aluminum, and magnesium.

16. The organic light-emitting transistor according to claim 1, wherein the functional emitting layer comprises:
a hole transport layer arranged on a side of the first source electrode away from the substrate;
an emitting layer arranged on a side of the hole transport layer away from the substrate; and
an electron transport layer arranged on a side of the emitting layer away from the substrate.

17. A light-emitting panel, comprising a plurality of organic light-emitting transistors according to claim 1.

18. The light-emitting panel according to claim 17, further comprising:
a switching transistor arranged between the substrate and the gate layer, the switching transistor comprising a second source electrode and a second drain electrode, and the second drain electrode being electrically connected with the gate layer and the second source electrode, respectively;
a thin film encapsulation layer arranged on a side of the first drain electrode away from the substrate;
a BM photoresist layer and a color film layer arranged on a side of the thin film encapsulation layer away from the substrate; and
a pixel definition layer arranged between a plurality of organic light-emitting transistors.

19. A preparation method for an organic light-emitting transistor, comprising:
S10: forming a gate layer on a side of the substrate;
S20: forming a gate insulating layer with a second grating structure on a side of the gate layer away from the substrate;
S30: forming a first source electrode with uniform thickness on a side of the gate insulating layer with the second grating structure away from the substrate, wherein a surface on a side of the first source electrode away from the substrate has a first grating structure;
S40: forming a functional emitting layer on a side of the first source electrode away from the substrate; and
S50: forming a first drain electrode on a side of the functional emitting layer away from the substrate.

20-27. (canceled)

28. A preparation method for an organic light-emitting transistor, comprising:
S100: forming a gate layer on a side of the substrate;
S200: forming a gate insulating layer with a plane on a side of the gate layer away from the substrate;
S300: forming a first source electrode with a first grating structure on a side of the gate insulating layer away from the substrate;
S400: forming a functional emitting layer on a side of the first source electrode away from the substrate; and
S500: forming a first drain electrode on a side of the functional emitting layer away from the substrate.

29-33. (canceled)
